(19) United States
(12) Patent Application Publication
(10) Pub. No.: US 2025/0357215 A1
(43) Pub. Date: Nov. 20, 2025

(54) PACKAGE STRUCTURE AND METHOD OF FORMING THE SAME

(71) Applicant: Taiwan Semiconductor Manufacturing Company, Ltd., Hsinchu (TW)

(72) Inventors: Chen-Shien CHEN, Hsinchu County (TW); Chi-Yen Lin, Tainan City (TW); Hsu-Hsien Chen, Hsinchu City (TW); Ting Hao Kuo, Hsinchu City (TW); Chang-Ching Lin, Hsinchu City (TW)

(73) Assignee: Taiwan Semiconductor Manufacturing Company, Ltd., Hsinchu (TW)

(21) Appl. No.: 19/286,261

(22) Filed: Jul. 31, 2025

Related U.S. Application Data
(63) Continuation of application No. 18/173,086, filed on Feb. 23, 2023.
(60) Provisional application No. 63/423,511, filed on Nov. 8, 2022.
(60) Provisional application No. 63/431,303, filed on Dec. 8, 2022.

(51) Int. Cl. H01L 21/78; H01L 23/00; H10B 80/00

(52) U.S. Cl. CPC H01L 21/78; H01L 23/564; H10B 80/00; H01L 24/05; H01L 24/06; H01L 24/08; H01L 24/80; H01L 2224/0557; H01L 2224/05624; H01L 2224/05644; H01L 2224/05647; H01L 2224/05657; H01L 2224/05684; H01L 2224/06181; H01L 2224/08145; H01L 2224/80006; H01L 2224/80357; H01L 2224/80379; H01L 2224/80895; H01L 2224/80896; H01L 2924/0504; H01L 2924/0544; H01L 2924/10156; H01L 2924/1431; H01L 2924/14361

(57) ABSTRACT

Provided are a package structure having stacked semiconductor dies with wavy sidewalls and a method of forming the same. The package structure includes: a first die and a second die bonded together; a first encapsulant laterally encapsulating the first die; and a second encapsulant laterally encapsulating the second die, wherein a second interface of the second die in contact with the second encapsulant is a wavy interface in a cross-sectional plane.

### CROSS-REFERENCE TO RELATED APPLICATION

This application is a continuation application of and claims the priority benefit of a prior application Ser. No. 18/173,086, filed on Feb. 23, 2023, now pending, which claims the priority benefit of U.S. provisional application Ser. No. 63/423,511, filed on Nov. 8, 2022 and U.S. provisional application Ser. No. 63/431,303, filed on Dec. 8, 2022. The entirety of the above-mentioned patent application is hereby incorporated by reference herein and made a part of this specification.

### BACKGROUND

Semiconductor devices are used in a variety of electronic applications, such as personal computers, cell phones, digital cameras, and other electronic equipment, as examples. Semiconductor devices are typically fabricated by sequentially depositing insulating or dielectric layers, conductive layers, and semiconductive layers of material over a semiconductor substrate, and patterning the various material layers using lithography to form circuit components and elements thereon. Dozens or hundreds of integrated circuits are typically manufactured on a single semiconductor wafer. The individual dies are singulated by sawing the integrated circuits along a scribe line. The individual dies are then packaged separately, in multi-chip modules, or in other types of packaging, for example.

The semiconductor industry continues to improve the integration density of various electronic components (e.g., transistors, diodes, resistors, capacitors, etc.) by continual reductions in minimum feature size, which allow more components to be integrated into a given area. As feature sizes continue to shrink in advanced semiconductor manufacturing nodes, new challenges arise that must be addressed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 to FIG. 4 are cross-sectional views of a method of forming a semiconductor die in accordance with some embodiments.

FIG. 5A to FIG. 5F are top views of a semiconductor die in accordance with various embodiments.

FIG. 6 to FIG. 7 are cross-sectional views of a method of forming a package structure in accordance with some embodiments.

FIG. 8 to FIG. 10 are cross-sectional views of a package structure in accordance with various embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

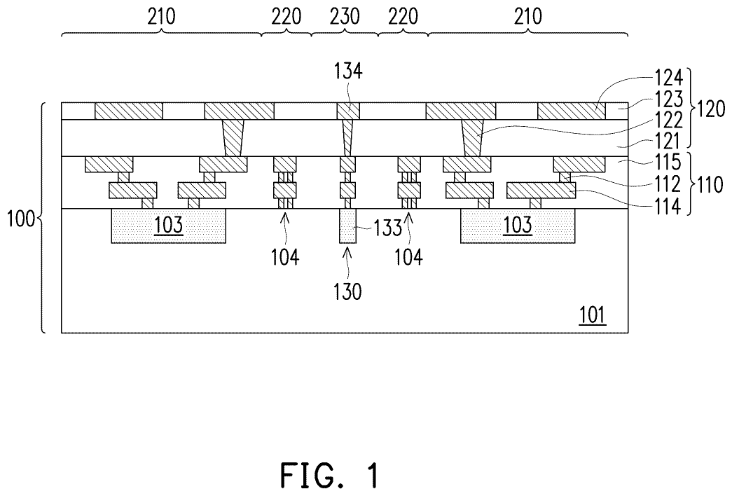

FIG. 1 to FIG. 4 are cross-sectional views of a method of forming a semiconductor die in accordance with some embodiments.

Referring to FIG. 1, a semiconductor device 100 is provided. In some embodiments, the semiconductor device 100 may be, e.g., a wafer that comprises a plurality of semiconductor dies, which the wafer is singulated later to form a plurality of individual semiconductor dies. The semiconductor device 100 may include a substrate 101, one or more electrical components 103, and an interconnect structure 110. The electrical components 103 are formed in or on the substrate 101. The interconnect structure 110 may be formed over the substrate 101 and electrically coupled to the electrical components 103. As illustrated in FIG. 1, the semiconductor device 100 may include different regions, such as a device region 210, a seal ring region 220, and a dicing region 230 (may also be referred to as a scribe line region). In some embodiments, functional circuits, such as integrated circuits that includes the electrical components 103 and the corresponding interconnect structure 110, are formed in the device region 210. A seal ring 104 may be formed in the seal ring region 220 around the device region 210. For example, the seal ring 104 may be formed in the seal ring region 220 to laterally surround the perimeter of a respective device region 210. A test key 130 may be formed in the dicing region 230. In some embodiments, the dicing region 230 is disposed, e.g., between adjacent seal ring regions 220. During a subsequent dicing process, the dicing is performed along (e.g., in) the dicing region 230 to singulate the wafer into a plurality of individual semiconductor dies. Note that for simplicity, FIG. 1 may only show portions of the semiconductor device 100, and not all details of the semiconductor device 100 are illustrated.

The substrate 101 may be a semiconductor substrate, such as silicon, doped or undoped, or an active layer of a semiconductor-on-insulator (SOI) substrate. The semiconductor substrate may include other semiconductor materials, such as germanium; a compound semiconductor including silicon carbide, gallium arsenic, gallium phosphide, gallium nitride, indium phosphide, indium arsenide, and/or indium antimonide; an alloy semiconductor including SiGe, GaAsP, AlInAs, AlGaAs, GaInAs, GaInP, and/or GaInAsP; or combinations thereof. Other substrates, such as multi-layered or gradient substrates, may also be used.

The electrical components 103, such as transistors, diodes, capacitors, resistors, etc., may be formed in and/or on the substrate 101 using any suitable formation method(s), and may be interconnected by the interconnect structure 110 to form functional circuits. For example, the electrical components 103 in each device region 210 are interconnected by the respective (e.g., overlying) interconnect structure 110 in that device region 210 to form the functional circuits of the integrated circuit die in the device region 210.

In some embodiments, the interconnect structure 110 includes metallization patterns (e.g., electrically conductive features) formed in one or more dielectric layers over the semiconductor substrate 101. For example, the interconnect structure 110 may include electrically conductive features, such as conductive lines 114 and vias 112 formed in a plurality of dielectric layers 115. In some embodiments, the dielectric layers 115 comprises a suitable dielectric material, such as silicon oxide, silicon nitride, silicon oxynitride, combinations thereof, multiple layers thereof, or the like, and may be formed using a suitable formation method such as chemical vapor deposition (CVD), physical vapor deposition (PVD), lamination, or the like. The electrically conductive features (e.g., 114, 112) of the interconnect structure 110 may be formed of an electrically conductive material, such as copper, and may be formed of a suitable formation method such as damascene, dual damascene, plating, or the like. Note that for simplicity, FIG. 1 illustrate the dielectric layer 115 as a single layer, with the understanding that the dielectric layer 115 of the interconnect structure 110 may include a plurality of dielectric layers.

FIG. 1 further illustrated the seal ring 104 formed in the seal ring region 220. As illustrated in FIG. 1, the seal ring 104 may include layers of vias and conductive lines formed in the dielectric layers 115. The seal ring 104 is formed in the same processing step(s) using the same material(s) as the conductive features 114/112, in some embodiments. In a top view, the seal ring 104 surrounds (e.g., encircles) a respective device region 210, in some embodiments. The seal ring 104 may protect the functional circuits in the device region 210 from mechanical stress and may also protect the functional circuits from damage due to cracking or peeling during the dicing process. In some embodiments, the seal ring 104 is electrically isolated, and therefore, do not perform any control or signal processing function.

Next, a dielectric layer 121, such as silicon oxide, may be formed over the interconnect structure 110, by using a suitable formation method such as CVD, PVD, or the like. A planarization process, such as chemical and mechanical planarization (CMP), may be performed to achieve a level upper surface for the dielectric layer 121.

Thereafter, a dielectric layer 123, such as silicon oxide or silicon nitride, is formed over the dielectric layer 121, by using a suitable formation method such as CVD, PVD, or the like. A plurality of conductive pads 124 are formed in the dielectric layer 123, and a plurality of vias 122 are formed to extend through the dielectric layer 121 to electrical couple the conductive pads 124 with the conductive features of the interconnect structures 110, thereby accomplishing a bonding structure 120. In some embodiments, the vias 122 may also be formed to contact the conductive pads 124 and the conductive lines 114. The conductive pads 124 and the vias 122 may be formed of a suitable conductive material, such as copper, gold, tungsten, cobalt, alloys thereof, combinations thereof, or the like, using a suitable method known or used in the industry. In some embodiments, the conductive pads 124 are electrically connected to the underlying electrical components 103 through with the interconnection structure 110 therebetween. In exemplary embodiments, the conductive pads 124 include one or more input/output (I/O) pads, bump pads or bond pads, for example.

FIG. 1 further illustrated the test key 130 formed in the dicing region 230. As illustrated in FIG. 1, the test key 130 may include a test device 133 formed in the substrate 101 and test pads 134 over the test device 133. In some embodiments, the conductive pads 124 located within the device region 210 and the test pads 134 located within the dicing region 230 are formed together during the same manufacturing processes. In certain embodiments, the material of the conductive pads 124 and the test pads 134 include aluminum (Al), aluminum alloy or combinations thereof.

In some embodiments, the test pads 134 are electrically connected to the underlying test device or test circuit 133 through the interconnection structure therebetween. In some embodiments, the test pads 134 include wafer acceptance testing (WAT) pads and/or optical critical dimension (OCD) pads. During wafer testing, the test pads 134 located on the scribe streets are electrically coupled to an external terminal through probe needles for testing. The test pads 134 are selected to test different properties of the wafer, such as leakage current, breakdown voltage, threshold voltage and effective channel length, saturation current, gate oxide thickness, critical dimension, contact resistance and connections. That is, in such embodiment, the test pads 134 is only electrically connected to the test device 133 in the dicing region 230, while not electrically connected to the electrical components 103 in the device region 210.

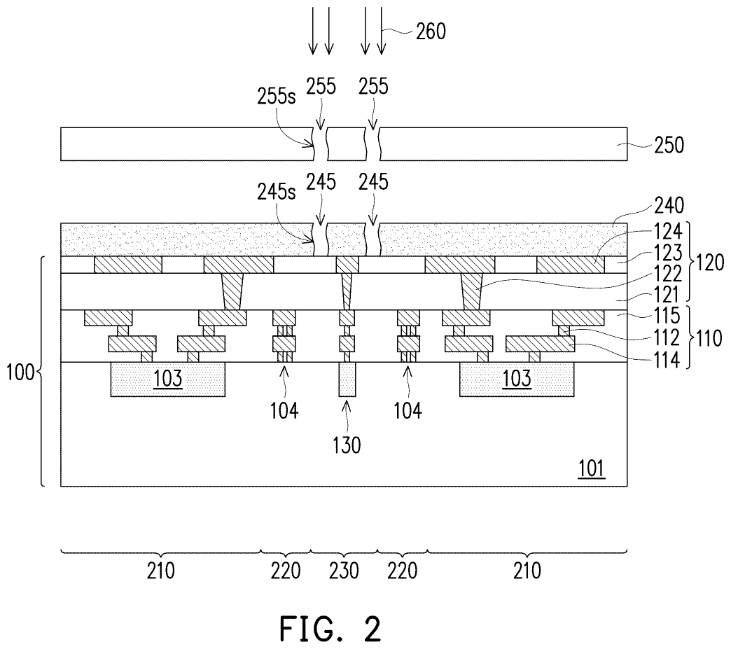

After forming the bonding structure 120, a photoresist material may be formed over the structure of FIG. 1. In some embodiments, the photoresist material covers the dielectric layer 123, the conductive pads 124, and the test pads 134. FIG. 2 illustrates irradiating the photoresist material with the laser beam 260 by using a mask 250 with openings 255 as photomask when the photoresist material includes negative photoresist. After performing a developing process, as shown in FIG. 2, the photoresist material is patterned to form a photoresist pattern 240 with openings 245. In some embodiments, the openings 255 in the mask 250 may correspond to the openings 245 in the photoresist pattern 240. In the top view, the openings 245 may laterally surround the test key 130 in the dicing region 230 to avoid the openings 245 that extends downwards from contacting the test key 130 during subsequent dicing processes.

It should be noted that the openings 255 in the mask 250 has a rounding or wavy sidewall 255s. In some embodiments, the wavy sidewall 255s is formed by optical proximity correction (OPC) which uses lithography enhancement techniques to adjust the profile of the sidewall 255s. In this case, the profile of the wavy sidewall 255s is duplicated into the photoresist pattern 240, so that the openings 245 also has the same wavy sidewall 245s. Furthermore, by using OPC, the top-view shape of the openings 245 and/or 255 may also have the perimeter with various arc, rounding, and wavy profiles, or the like.

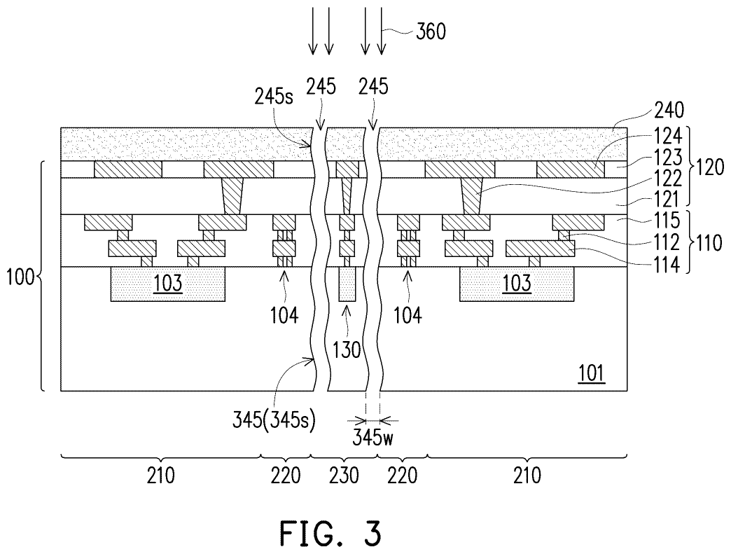

Referring to FIG. 3, a dicing process 360, such as a plasma dicing process, may be performed along the dicing paths in the dicing regions 230 to form openings 345 (e.g., trenches in a top view). The plasma dicing process 360 may etch portions of the semiconductor device 100 exposed by the patterns (e.g., openings 245) in the photoresist pattern 240. In some embodiments, the openings 345 may extend through the dielectric layers 123/121/115 to reach a bottom surface of the substrate 101. In other words, the openings 345 also extend through the substrate 101. In some alternative embodiments, the openings 345 may extend into, but not through, the substrate 101, and then a backside grinding process, such as CMP, may be performed from the backside of the substrate 101 (e.g., the side facing away from the interconnect structure 110) to reduce the thickness of the substrate 101, therefore separating the semiconductor device 100 (e.g., a wafer).

In some embodiments, the plasma dicing process is a dry plasma process such as Deep Reactive Ion Etching (DRIE), which include using the fluorine containing etchant such as CF₄, SF₆, F-base related gas, the like, or a combination thereof. The plasma dicing process can etch very narrow, deep vertical trenches into the substrate to separate individual dies. Issues with dicing using a blade, such as die chipping or cracking, may be avoided by the plasma dicing process, thereby improving the yield of the manufacturing process. Unlike dicing using a blade, the plasma dicing process avoids or reduces damage to the wafer surface and/or sidewalls, resulting in greater die strengths, improved device reliability, and increased device lifetime. Due to the narrower dicing path of the plasma dicing process, the dicing regions may be made narrower, thus allowing for more dies to be formed in the wafer to reduce production cost per die. In addition, the plasma dicing process may be performed along multiple dicing paths simultaneously, thus increasing the throughput of the manufacturing process.

It should be noted that, the openings 245 in the photoresist pattern 240 are designed to remove the dielectric layers 123/121/115 laterally surrounding the test key 130 in the dicing region 230, so that the openings 345 are not in contact with the test key 130. That is, during the plasma dicing process 360, only the dielectric layers 123/121/115 directly below the openings 245 are removed without encountering the conductive features in the interconnect structure 110, the conductive features in the bonding structure 120, and the test key 130. In some embodiments, the etch rate of the conductive features (e.g., metal) is lower than that of the dielectric layers (e.g., silicon oxide) during the plasma dicing process. If the plasma dicing process encounters the conductive features (e.g., metal), the opening 345 will not easily penetrate through the semiconductor device 100 and the profile of the sidewall of the opening 345 will become sharper. The sharp sidewall may cause the stress concentration thereby resulting in the undesired crack.

In the present embodiment, the plasma dicing process 360 can easily replicate the profile of the opening 245 so that the opening 345 has the same wavy sidewall 345s. Unlike dicing using a blade, the sidewall 345s of the openings 345 may have the smoother surface and profile after the plasma dicing process 360. In some embodiments, the opening 345 has an average width 345w in a range from about 1 μm to about 100 μm such as 10 μm. When the average width 345w is less than 1 μm, the openings 345 are difficult to maintain the smooth or wavy sidewall 345s. When the average width 345w is greater than 100 μm, the openings 345 may be in contact with the test key 130, thereby forming the sharp sidewall. Furthermore, by defining the shape of the openings 245 in the photoresist pattern 240 and the plasma dicing process 360, the top-view shape of the openings 345 may also have the perimeter with various arc, rounding, and wavy profiles, or the like. In some embodiments, the opening 345 is not in contact with the conductive features in the interconnect structure 110, the conductive features in the bonding structure 120, and the test key 130. That is, the sidewall 345s of the opening 345 is free of metal material.

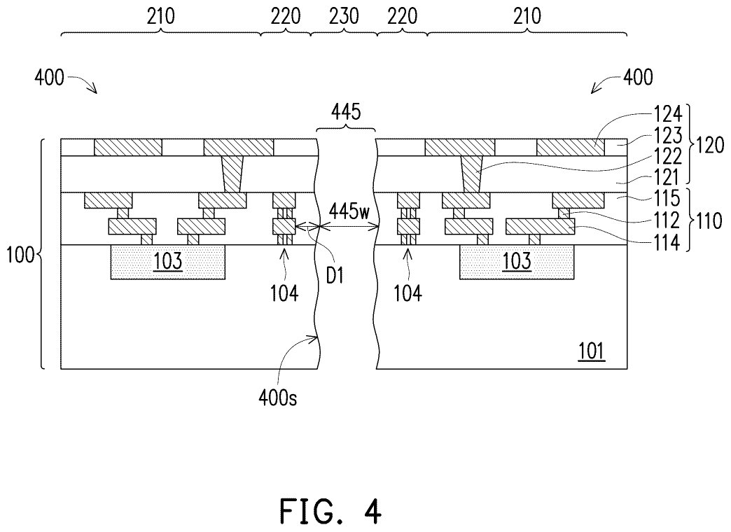

Referring to FIG. 4, after removing the photoresist pattern 240 and the portion of the semiconductor device 100 between the openings 345, the semiconductor device 100 is singulated to form a plurality of individual semiconductor dies 400. In some embodiments, an opening 445 is formed to penetrate through the semiconductor device 100 to divided the semiconductor device 100 into the semiconductor dies 400. In some embodiments, the opening 445 may have an average width 445w in a range from about 10 μm to about 500 μm such as 120 μm. As above, each of the semiconductor dies 400 may have the smooth or wavy sidewall 400s, and the top-view shape of each of the semiconductor dies 400 may also have the perimeter with various arc, rounding, and wavy profiles, or the like, details of which are discussed below. In some embodiments, the sidewall 400s of the semiconductor die 400 is physically separated from the seal ring 104 by the dielectric layer 115 by a distance D1 of about 1 μm to about 1000 μm such as 200 μm.

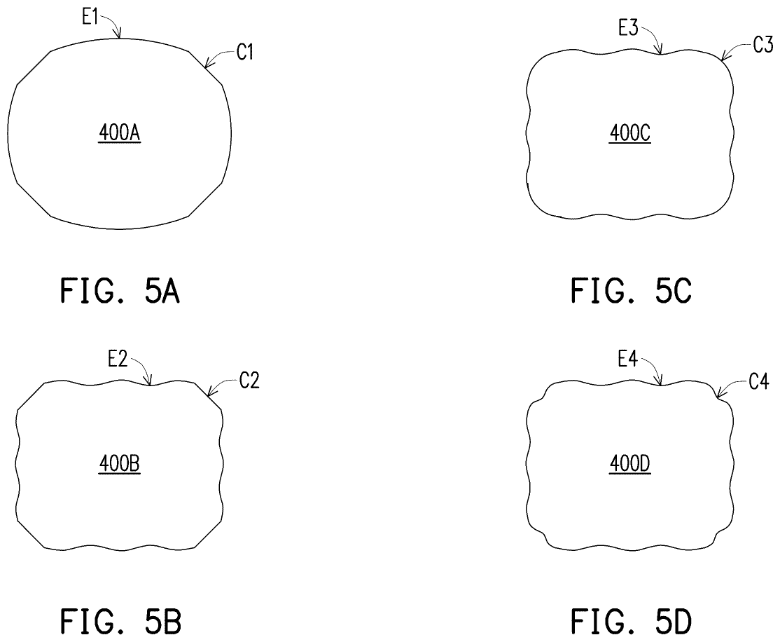

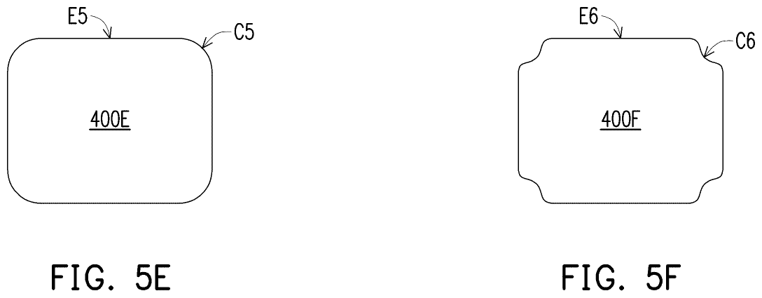

FIG. 5A to FIG. 5F are top views of a semiconductor die in accordance with various embodiments.

Referring to FIG. 5A, a semiconductor die 400A is provided to have four corners C1 and four edges E1. In some embodiments, the corner C1 has a flat side and the edge E1 has an arc side. Compared with the flat side, the arc side may have one wave crest. That is, the slope of each point of the edge E1 is continuously changing.

Referring to FIG. 5B, a semiconductor die 400B is provided to have four corners C2 and four edges E2. In some embodiments, the corner C2 has a flat side and the edge E2 has a wavy side. Compared with the arc side having one wave crest, the wavy side may have at least one wave crest and at least one wave trough connected to each other. That is, the slope of each point of the edge E2 is continuously changing. In some embodiments, the edge E2 has a plurality of wave crests and a plurality of wave trough connected to each other. In this case, the wavelength measured by two adjacent wave crests may be greater than or equal to 1 μm, and the amplitude of the wave crest may be greater than or equal to 1 μm.

Referring to FIG. 5C, a semiconductor die 400C is provided to have four corners C3 and four edges E3. In some embodiments, the corner C3 has an arc side and the edge E3 has a wavy side. Compared with the corner C2 having the flat side, the arc or curved corner C3 may have one wave crest. In some embodiments, the arc or curved corner C3 has the curvature radius in a range of about 1 μm to about 100 μm such as 10 μm.

Referring to FIG. 5D, a semiconductor die 400D is provided to have four corners C4 and four edges E4. In some embodiments, the corner C4 has a wavy side and the edge E4 has a wavy side. Compared with the arc corner C3, the corner C4 with the wavy side may have at least one wave crest and at least one wave trough connected to each other. That is, the slope of each point of the corner C4 is continuously changing. In some embodiments, the corner C4 has a plurality of wave crests and a plurality of wave trough connected to each other. In this case, the wavelength measured by two adjacent wave crests may be greater than or equal to 1 μm, and the amplitude of the wave crest may be greater than or equal to 1 μm.

Referring to FIG. 5E, a semiconductor die 400E is provided to have four corners C5 and four edges E5. In some embodiments, the corner C5 has an arc side and the edge E5 has a flat side.

Referring to FIG. 5F, a semiconductor die 400F is provided to have four corners C6 and four edges E6. In some embodiments, the corner C6 has a wavy side and the edge E6 has a flat side.

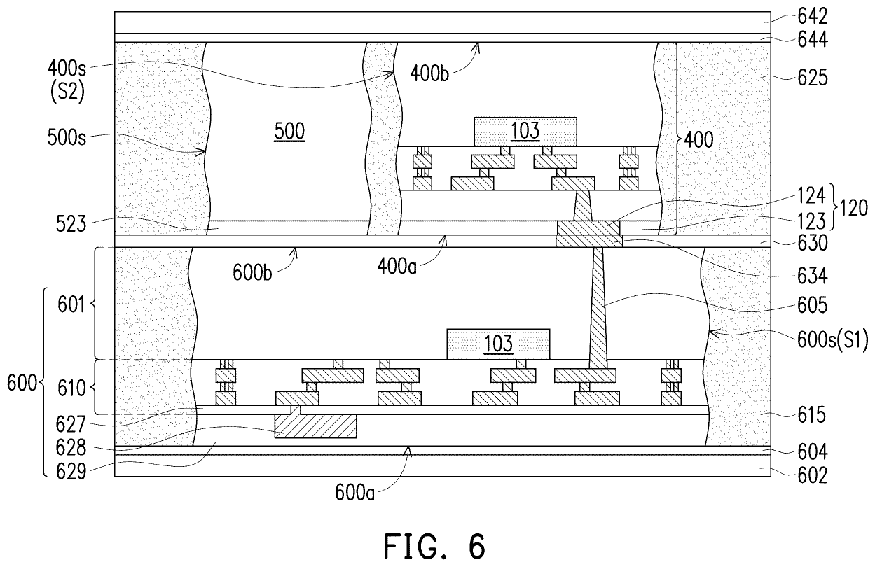

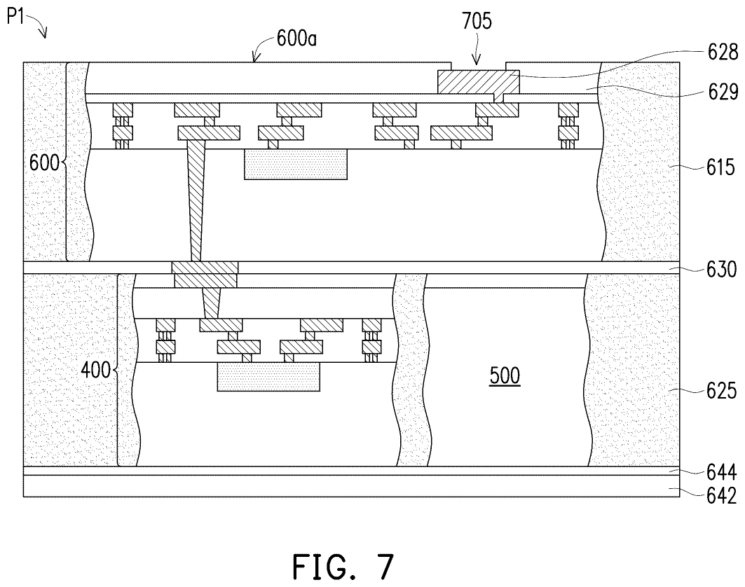

FIG. 6 to FIG. 7 are cross-sectional views of a method of forming a package structure in accordance with some embodiments.

Referring to FIG. 6, a carrier 602 is provided. In some embodiments, the carrier 602 may be made of a material such as silicon, polymer, polymer composite, metal foil, ceramic, glass, glass epoxy, beryllium oxide, tape, or other suitable material for structural support. In the embodiment, the carrier 602 is a glass substrate.

A dielectric layer 604 is formed on the carrier 602. In some embodiments, the dielectric layer 604 may be a photosensitive polybenzoxazole (PBO) or polyimide (PI) layer formed on the carrier 602, for example. In alternative embodiments, the dielectric layer 604 may be made from other photosensitive or non-photosensitive dielectric materials, such as silicon oxide, silicon nitride, low-k dielectrics such as carbon doped oxides, extremely low-k dielectrics such as porous carbon doped silicon dioxide, combinations of these, or the like.

A first die 600 is provided. In some embodiments, the first die 600 include system on a chips or system on chips (SoC) including several different integrated circuits, i.e., ICs or processors, together with memories and I/O interfaces. Each of the integrated circuit integrates various components of a computer or other electronic systems into one semiconductor chip. The various components contain digital, analog, mixed-signal, and often radio-frequency functions. Also, the SoC integrates processors (or controllers) with advanced peripherals like a graphics processing unit (GPU), a Wi-Fi module, or a co-processor. In the architecture of the SoC, both logic components and memory components are fabricated in the same silicon wafer. For high efficiency computing or mobile devices, multi-core processors are used, and the multi-core processors include large amounts of memories, such as several gigabytes. In some alternative embodiments, the first die 600 may be the application-specific integrated circuit (ASIC) die. In some other embodiments, the first die 600 is a logic die.

Specifically, the first die 600 may include a substrate 601 and an interconnect structure 610 over the substrate 601. The material and forming method of the substrate 601 and the interconnect structure 610 are similar to the material and forming method of the substrate 101 and the interconnect structure 110 illustrated in above embodiments. Thus, details thereof are omitted here.

The first die 600 further includes a first passivation layer 627, a conductive pad 628, and a second passivation layer 629. The first passivation layer 627 may be formed over the interconnect structure 610 in order to provide a degree of protection for the underlying structures. The first passivation layer 627 may be formed of one or more suitable dielectric materials such as silicon oxide, silicon nitride, low-k dielectrics such as carbon doped oxides, extremely low-k dielectrics such as porous carbon doped silicon dioxide, combinations of these, or the like. The first passivation layer 627 may be formed through a process such as CVD, although any suitable process may be utilized. The conductive pad 628 may be formed over the first passivation layer 627 and electrically coupled to underlying electrically conductive features of the interconnect structure 610. The conductive pad 628 may comprise aluminum, but other materials, such as copper, may alternatively be used. The conductive pad 628 may be formed by using any other suitable process. The second passivation layer 629 may be formed to overlay the surface of the conductive pad 628 and the first passivation layer 627. The second passivation layer 629 may be formed of one or more suitable dielectric materials such as silicon oxide, silicon nitride, low-k dielectrics such as carbon doped oxides, extremely low-k dielectrics such as porous carbon doped silicon dioxide, combinations of these, or the like. The second passivation layer 629 may be formed through a process such as CVD, although any suitable process may be utilized.

The first die 600 is picked and placed on the carrier 602. Specifically, the first die 600 may have a frontside 600a and a backside 600b opposite to each other. The frontside 600a of the first die 600 faces toward the carrier 602, while the backside 600b of the first die 600 faces upside. The frontside 600a of the first die 600 may be bonded onto the carrier 602 by non-metal-to-non-metal bonding such as dielectric-to-dielectric bonding or fusion bonding. In some embodiments, the first die 600 is attached to the carrier 602 by contacting the dielectric layer 604 with the second passivation layer 629.

Next, a first encapsulant 615 is formed on the carrier 602 to laterally encapsulate the first die 600. In some embodiments, the first encapsulant 615 includes an inorganic dielectric, which may be an oxide-based dielectric, such as silicon oxide. For example, the silicon oxide may be formed of tetraethoxysilane (TEOS). The forming method may include Chemical Vapor Deposition (CVD), High-Density Plasma Chemical Vapor Deposition (HDPCVD), or the like. In the present embodiment, the first encapsulant 615 may be referred to as the gap-filling layer. In some alternative embodiments, the first encapsulant 615 includes a molding compound, a molding underfill, a resin such as epoxy, a combination thereof, or the like. The forming method of the first encapsulant 615 includes a molding process, a molding underfilling (MUF) process, or a combination thereof.

It should be noted that the first die 600 has a wavy sidewall 600s formed by the steps illustrated in FIG. 1 to FIG. 4. In such embodiment, the interface S1 that the sidewall 600s of the first die 600 is in contact with the first encapsulant 615 is also a smooth or wavy interface in the cross-sectional plane of FIG. 6. Compared with the flat or vertical interface, the wavy interface S1 is able to increase the contact area between the sidewall 600s of the first die 600 and the first encapsulant 615, thereby enhancing the adhesion between the sidewall 600s of the first die 600 and the first encapsulant 615. In addition, the smooth interface S1 is able to decrease the stress, thereby avoiding the crack and/or delamination issue of the first encapsulant 615 and improving the reliability. Compared with the flat or vertical interface, the smooth or wavy interface S1 may have at least one wave crest and at least one wave trough connected to each other. That is, the slope of each point of the interface S1 is continuously changing. In some embodiments, the interface S1 is free of metal material.

Thereafter, a dielectric layer 630, such as silicon oxide or silicon nitride, is formed over the first encapsulant 615 and the backside 600b of the first die 600, by using a suitable formation method such as CVD, PVD, or the like. A conductive pad 634 is formed in the dielectric layer 630 to electrical couple the conductive features of the interconnect structures 610 by a through semiconductor via (TSV) 605 embedded in the substrate 601.

After forming the conductive pad 634 in the dielectric layer 630, a second die 400 and a third die 500 are picked and placed on the backside 600b of the first die 600 side by side. Specifically, the second die 400 may have a frontside 400a and a backside 400b opposite to each other. The frontside 400a of the second die 400 faces toward the backside 600b of the first die 600, while the backside 400b of the second die 400 faces upside. The frontside 400a of the second die 400 may be bonded onto the backside 600b of the first die 600 by hybrid bonding. In some embodiments, the hybrid bonding involves at least two types of bonding, including metal-to-metal bonding and non-metal-to-non-metal bonding such as dielectric-to-dielectric bonding or fusion bonding. In some embodiments, the second die 400 is attached to the first die 600 by contacting the conductive pad 124 with the conductive pad 634 and the dielectric layer 123 with the dielectric layer 630. In some embodiments, the first die 600 and the second die 400 may be a same type of dies or different types of dies. The second die 400 may include a memory die such as high bandwidth memory (HBM) die. In the present embodiment, the first die 600 is the logic die and the second die 400 is the memory die.

On the other hand, the third die 500 may be bonded onto the backside 600b of the first die 600 by non-metal-to-non-metal bonding such as dielectric-to-dielectric bonding or fusion bonding. In some embodiments, the third die 500 is attached to the first die 600 by contacting the dielectric layer 523 with the dielectric layer 630. In the embodiment, the third die 500 is a dummy die. Herein, when elements are described as “dummy”, the elements are electrically floating or electrically isolated from other elements. For example, the third die 500 does not include functional circuits, devices or metallization structures therein.

Next, a second encapsulant 625 is formed on the dielectric layer 630 to laterally encapsulate the second die 400 and the third die 500. In some embodiments, the second encapsulant 625 includes an inorganic dielectric, which may be an oxide-based dielectric, such as silicon oxide. For example, the silicon oxide may be formed of tetraethoxysilane (TEOS). The forming method may include Chemical Vapor Deposition (CVD), High-Density Plasma Chemical Vapor Deposition (HDPCVD), or the like. In the present embodiment, the second encapsulant 625 may be referred to as the gap-filling layer. In some alternative embodiments, the second encapsulant 625 includes a molding compound, a molding underfill, a resin such as epoxy, a combination thereof, or the like. The forming method of the second encapsulant 625 includes a molding process, a molding underfilling (MUF) process, or a combination thereof.

It should be noted that the second die 400 has the wavy sidewall 400s formed by the steps illustrated in FIG. 1 to FIG. 4. In such embodiment, the interface S2 that the sidewall 400s of the second die 400 is in contact with the second encapsulant 625 is also a smooth or wavy interface in the cross-sectional plane of FIG. 6. Compared with the flat or vertical interface, the wavy interface S2 is able to increase the contact area between the sidewall 400s of the second die 400 and the second encapsulant 625, thereby enhancing the adhesion between the sidewall 400s of the second die 400 and the second encapsulant 625. In addition, the smooth interface S2 is able to decrease the stress, thereby avoiding the crack and/or delamination issue of the second encapsulant 625 and improving the reliability. In some embodiments, the interface S2 is free of metal material. Further, the third die 500 also has a smooth or wavy sidewall 500s which can further increase the adhesion and decrease the stress, thereby avoiding the crack and/or delamination issue of the second encapsulant 625 and improving the reliability.

Thereafter, an additional carrier 642 with a dielectric layer 644 thereon is formed over the backside 400b of the second die 400, the third die 500, and the second encapsulant 625.

Referring to FIG. 7, the structure illustrated in FIG. 6 is flipped upside down, so that the frontside 600a of the first die 600 faces upside. Next, the carrier 602 and the dielectric layer 604 are removed by a grinding process to expose the second passivation layer 629 and the first encapsulant 615. The second passivation layer 629 is then patterned to form an opening 705, thereby accomplishing a package structure P1. In some embodiments, the opening 705 exposes the conductive pad 628 for connecting to the external circuit or component.

Although the said embodiment provides a package structure with a face-to-back configuration, the embodiments of the present invention are not limited thereto. In some alternative embodiments, other package structures with a face-to-face configuration are also provided as below.

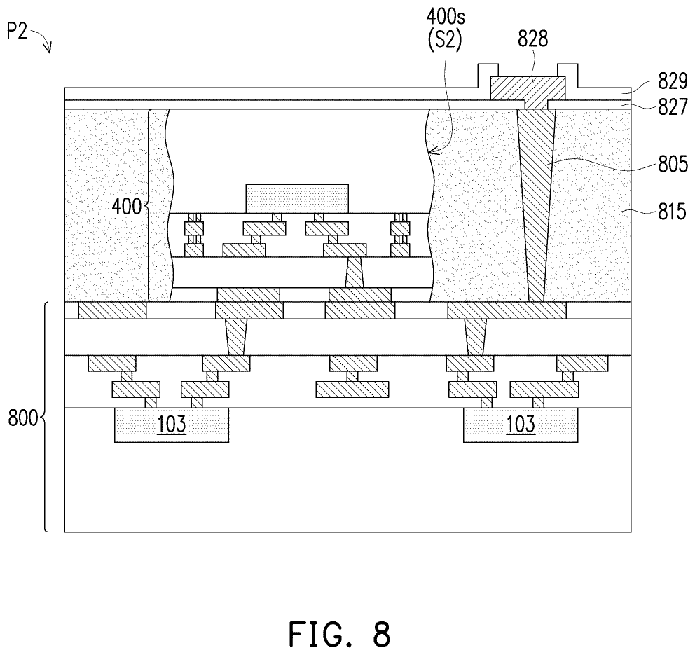

FIG. 8 to FIG. 10 are cross-sectional views of a package structure in accordance with various embodiments.

Referring to FIG. 8, a bottom die 800 is provided. In some embodiments, the bottom die 800 may be an application-specific integrated circuit (ASIC) chip, an analog chip, a sensor chip, a wireless and radio frequency chip, a voltage regulator chip or a memory chips, for example. In the present embodiment, the bottom die 800 may be a wafer having a plurality of dies with a same function or different functions. In detail, the bottom die 800 includes a substrate, an interconnect structure, and a bonding structure, which has been described in the above paragraphs and will not be repeated here.

Next, a top die 400 is turned upside down and mounted onto the bottom die 800. In detail, the top die 400 and the bottom die 800 are face-to-face bonded together by hybrid bonding. In some embodiments, the hybrid bonding involves at least two types of bonding, including metal-to-metal bonding and non-metal-to-non-metal bonding such as dielectric-to-dielectric bonding or fusion bonding.

After the bonding, an encapsulant 815 is formed on the bottom die 800 to laterally encapsulate the top die 400. In some embodiments, the encapsulant 815 includes an inorganic dielectric, which may be an oxide-based dielectric, such as silicon oxide. For example, the silicon oxide may be formed of tetraethoxysilane (TEOS). The forming method may include Chemical Vapor Deposition (CVD), High-Density Plasma Chemical Vapor Deposition (HDPCVD), or the like. In the present embodiment, the encapsulant 815 may be referred to as the gap-filling layer. In some alternative embodiments, the encapsulant 815 includes a molding compound, a molding underfill, a resin such as epoxy, a combination thereof, or the like. The forming method of the encapsulant 815 includes a molding process, a molding underfilling (MUF) process, or a combination thereof.

It should be noted that the top die 400 has the wavy sidewall 400s formed by the steps illustrated in FIG. 1 to FIG. 4. In such embodiment, the interface S2 that the sidewall 400s of the top die 400 is in contact with the encapsulant 815 is also a smooth or wavy interface in the cross-sectional plane of FIG. 8. Compared with the flat or vertical interface, the wavy interface S2 is able to increase the contact area between the sidewall 400s of the top die 400 and the encapsulant 815, thereby enhancing the adhesion between the sidewall 400s of the top die 400 and the encapsulant 815. In addition, the smooth interface S2 is able to decrease the stress, thereby avoiding the crack and/or delamination issue of the encapsulant 815 and improving the reliability.

Thereafter, at least one through dielectric via (TDV) 805 is formed in the encapsulant 815 to electrically connect to the bottom die 800 and the to-be-formed conductive pad 828. In some embodiments, the TDV 805 includes a conductive via. The conductive via is made of copper, copper alloys, aluminum, aluminum alloys, or combinations thereof. In some other embodiments, the TDV 805 further includes a diffusion barrier layer (not shown) surround the conductive via. The diffusion barrier layer is made of Ta, TaN, Ti, TiN, CoW or a combination thereof, and may be formed by a suitable process such as electro-chemical plating process, CVD, atomic layer deposition (ALD), PVD or the like.

After forming the TDV 805, a first passivation layer 827 may be formed over the top die 400 and the encapsulant 815 in order to provide a degree of protection for the underlying structures. The first passivation layer 827 may be formed of one or more suitable dielectric materials such as silicon oxide, silicon nitride, low-k dielectrics such as carbon doped oxides, extremely low-k dielectrics such as porous carbon doped silicon dioxide, combinations of these, or the like. The first passivation layer 827 may be formed through a process such as CVD, although any suitable process may be utilized. A conductive pad 828 is formed over the first passivation layer 827 and electrically coupled to underlying TDV 805. The conductive pad 828 may comprise aluminum, but other materials, such as copper, may alternatively be used. The conductive pad 828 may be formed by using any other suitable process. A second passivation layer 829 may be formed to overlay a portion of the conductive pad 828 and the first passivation layer 827, thereby accomplishing a package structure P2. The second passivation layer 829 may be formed of one or more suitable dielectric materials such as silicon oxide, silicon nitride, low-k dielectrics such as carbon doped oxides, extremely low-k dielectrics such as porous carbon doped silicon dioxide, combinations of these, or the like. The second passivation layer 829 may be formed through a process such as CVD, although any suitable process may be utilized.

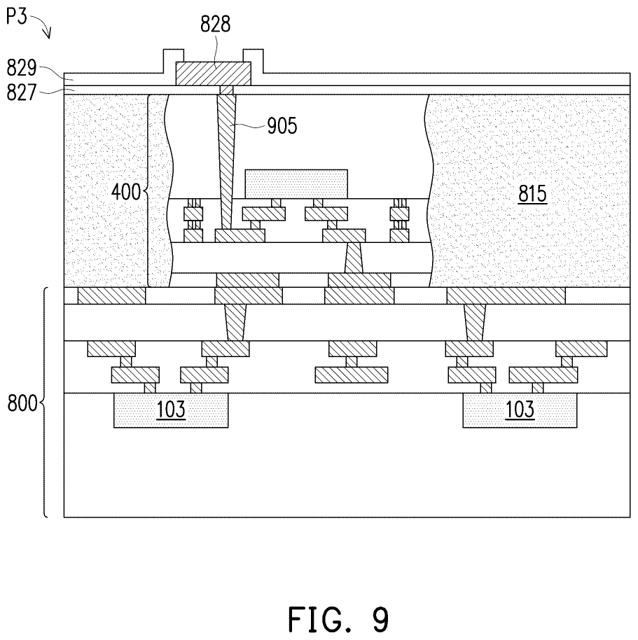

Referring to FIG. 9, a package structure P3 of FIG. 9 is similar to the package structure P2 of FIG. 8. A main difference therebetween lies in that the package structure P3 further includes a TSV 905 embedded in the top die 400 to electrically couple the interconnect structure of the top die 400 with the conductive pad 828 for connecting to the external circuit or component.

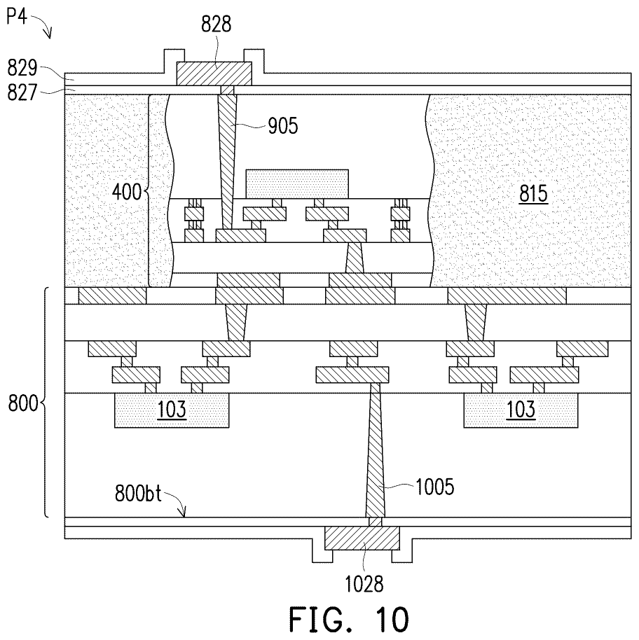

Referring to FIG. 10, a package structure P4 of FIG. 10 is similar to the package structure P3 of FIG. 9. A main difference therebetween lies in that the package structure P4 further includes a TSV 1005 embedded in the bottom die 800 to electrically couple the interconnect structure of the bottom die 800 with the conductive pad 1028 for connecting to the external circuit or component. In such embodiment, the package structure P4 may be referred to as the chip-on-wafer (CoW) package structure with dual-side terminals.

Moreover, although the said embodiment uses the system on integrated chip (SoIC) package structure as an example to illustrate the packaging structure having one or more semiconductor dies with the wavy sidewall, the embodiments of the present invention are not limited thereto. In other embodiments, the semiconductor dies with the wavy sidewall may be applied to any suitable package structure, such as package on package (POP) package structure, integrated fan-out (InFO) package structure, chip on wafer on substrate (CoWoS®) package structure, or the like.

According to some embodiments, a semiconductor die includes: a device region; a dicing region, laterally surrounding the device region; and a seal ring region, laterally disposed between the device region and the dicing region, wherein the semiconductor die has a wavy sidewall at the cross-section in the dicing region.

According to some embodiments, a semiconductor die includes: a first die and a second die bonded together; a first encapsulant, laterally encapsulating the first die; and a second encapsulant, laterally encapsulating the second die, wherein a second interface of the second die in contact with the second encapsulant is a wavy interface in a cross-sectional plane.

According to some embodiments, a method of forming a semiconductor die includes: providing a semiconductor device having a device region, a dicing region, and a seal ring region laterally disposed between the device region and the dicing region; forming a photoresist pattern over the semiconductor device; performing a plasma dicing process by using the photoresist pattern to from a plurality of first openings in the dicing region, wherein the plurality of first openings laterally surround a test key in the dicing region; and removing a portion of the semiconductor device between the plurality of first openings to form a second opening penetrating through the semiconductor device in the dicing region, thereby singulating the semiconductor device into a plurality of semiconductor dies, wherein the plurality of semiconductor dies have wavy sidewalls at the cross-section in the dicing region.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A package structure, comprising:
a first die;
a second die, disposed on the first die, wherein when viewed in cross section the second die has a wavy sidewall; and
a gap-filling layer, disposed on the first die and laterally encapsulating the second die.

2. The package structure of claim 1, wherein the wavy sidewall has at least one wave crest and at least one wave trough connected to each other.

3. The package structure of claim 2, wherein an amplitude of the at least one wave crest is greater than or equal to 1 μm.

4. The package structure of claim 2, wherein a wavelength measured by two adjacent wave crests is greater than or equal to 1 μm.

5. The package structure of claim 2, wherein the second die further comprises:
a substrate;
an interconnect structure, disposed over the substrate; and
a seal ring, embedded in the interconnect structure to laterally surround an electrical component in the substrate, wherein a first distance between the seal ring and the gap-filling layer at the at least one wave crest is different from a second distance between the seal ring and the gap-filling layer at the at least one wave trough.

6. The package structure of claim 5, further comprising:
a conductive pad, disposed over the second die; and
a through semiconductor via (TSV), penetrating through the substrate to electrically connect the interconnect structure and the conductive pad.

7. The package structure of claim 1, wherein the gap-filling layer interfaces with the second die at the wavy sidewall.

8. The package structure of claim 1, further comprising:
a conductive pad, disposed over the gap-filling layer; and
a through dielectric via (TDV), disposed over the first die and penetrating through the gap-filling layer to electrically connect the first die and the conductive pad.

9. A package structure, comprising:
a bottom die, wherein a perimeter of the bottom die has four edges and four corners in a top view, and the four corners each have a curved corner; and
a first gap-filling layer, surrounding the perimeter of the bottom die.

10. The package structure of claim 9, wherein the four edges each have a wavy side.

11. The package structure of claim 9, further comprising:
a top die, disposed on the bottom die;
a dummy die, disposed on the bottom die and aside the top die; and
a second gap-filling layer, disposed on the bottom die and laterally encapsulating the top die and the dummy die, wherein an interface of the top die interfacing with the second gap-filling layer is a wavy interface in a cross-sectional view.

12. The package structure of claim 11, wherein a perimeter of the top die falls within the perimeter of the bottom die.

13. The package structure of claim 11, wherein the interface is free of metal material.

14. The package structure of claim 11, wherein a backside of the bottom die faces a frontside of the top die, and the backside of the bottom die is bonded onto the frontside of the top die by a metal-to-metal bonding and a dielectric-to-dielectric bonding.

15. The package structure of claim 11, wherein a frontside of the bottom die faces a frontside of the top die, and the frontside of the bottom die is bonded onto the frontside of the top die by a metal-to-metal bonding and a dielectric-to-dielectric bonding.

16. The package structure of claim 11, wherein a material of the first gap-filling layer comprises an inorganic dielectric material.

17. A method of forming a package structure, comprising:
bonding a top die onto a bottom die by a direct bonding;
forming a first gap-filling layer to surround a perimeter of the bottom die, wherein the perimeter of the bottom die has four edges and four corners in a top view, and the four corners each have a curved corner; and
forming a second gap-filling layer to surround a perimeter of the top die.

18. The method of claim 17, wherein the four edges each have a wavy side.

19. The method of claim 17, further comprising:
bonding a dummy die onto the bottom die, wherein the second gap-filling layer further surrounds a perimeter of the dummy die.

20. The method of claim 17, wherein a material of the first and second gap-filling layers comprises an inorganic dielectric material.
